(19) United States
(12) Patent Application Publication
(10) Pub. No.: US 2023/0109237 A1
(43) Pub. Date: Apr. 6, 2023

(54) STRAIN GAUGE

(71) Applicant: MINEBEA MITSUMI Inc., Nagano (JP)

(72) Inventors: Shinya TODA, Nagano (JP); Shintaro TAKATA, Nagano (JP); Toshiaki ASAKAWA, Nagano (JP); Yuta AIZAWA, Nagano (JP)

(21) Appl. No.: 17/906,081

(22) PCT Filed: Mar. 18, 2021
(86) PCT No.: PCT/JP2021/011195

§ 371 Date: Sep. 12, 2022

(30) Foreign Application Priority Data
Mar. 24, 2020 (JP) 2020-052359
Mar. 3, 2021 (JP) 2021-033200

(51) Int. Cl. G01L 1/22; G01B 7/16; C23C 14/00; C23C 14/08

(52) U.S. Cl. CPC G01L 1/2287; G01B 7/16; C23C 14/0036; C23C 14/08

(57) ABSTRACT

A strain gauge includes a flexible resin substrate and a resistor formed of material including at least one of chromium or nickel, the resistor being situated on one side of the substrate. The strain gauge includes a conductive layer formed on the other side of the substrate.

### TECHNICAL FIELD

The present invention relates to a strain gauge.

### BACKGROUND ART

A strain gauge is known to be attached to a measured object to detect strain of the measured object. The strain gauge includes a resistor used for detecting the strain. As a resistor material, for example, material including Cr (chromium) or Ni (nickel) is used. The resistor is formed on a substrate made of, for example, an insulating resin (see, for example, Patent Document 1).

### CITATION LIST

### Patent Document

[Patent Document 1] Japanese Unexamined Patent Application Publication No. 2016-74934

### SUMMARY

However, in a conventional strain gauge, noise superimposed at the resistor is relatively increased, and thus it may result in reductions in measurement accuracy.

An object of the present invention is to provide a strain gauge that is capable of reducing noise superimposed at a resistor.

A strain gauge includes a flexible resin substrate and a resistor formed of material including at least one of chromium or nickel, the resistor being situated on one side of the substrate. The strain gauge includes a conductive layer formed on the other side of the substrate.

### Effects of the Invention

According to a disclosed technique, a strain gauge that is capable of reducing noise superimposed at a resistor can be provided.

### BRIEF DESCRIPTION OF DRAWINGS

FIG. 1 is a plan view of an example of a strain gauge according to a first embodiment;

FIG. 2 is a cross-sectional view (first part) of an example of the strain gauge according to the first embodiment;

FIG. 3 is a cross-sectional view (second part) of an example of the strain gauge according to the first embodiment;

FIG. 4 is a cross-sectional view (third part) of an example of the strain gauge according to the first embodiment;

FIG. 5 is a cross-sectional view of an example of the strain gauge according to a first modification of the first embodiment;

FIG. 6 is a cross-sectional view of an example of the strain gauge according to a second modification of the first embodiment;

FIG. 7 is a cross-sectional view of an example of the strain gauge according to a third modification of the first embodiment;

FIG. 8 is a cross-sectional view of an example of the strain gauge according to a fourth modification of the first embodiment;

FIG. 9A is a diagram illustrating the measurement result for noise in a comparative example; and

FIG. 9B is a diagram illustrating the measurement result for noise according to an example.

### DESCRIPTION OF EMBODIMENTS

One or more embodiments will be described below with reference to the drawings. In each figure, the same numerals denote the same components, and accordingly, duplicative description of thereof may be omitted.

### First Embodiment

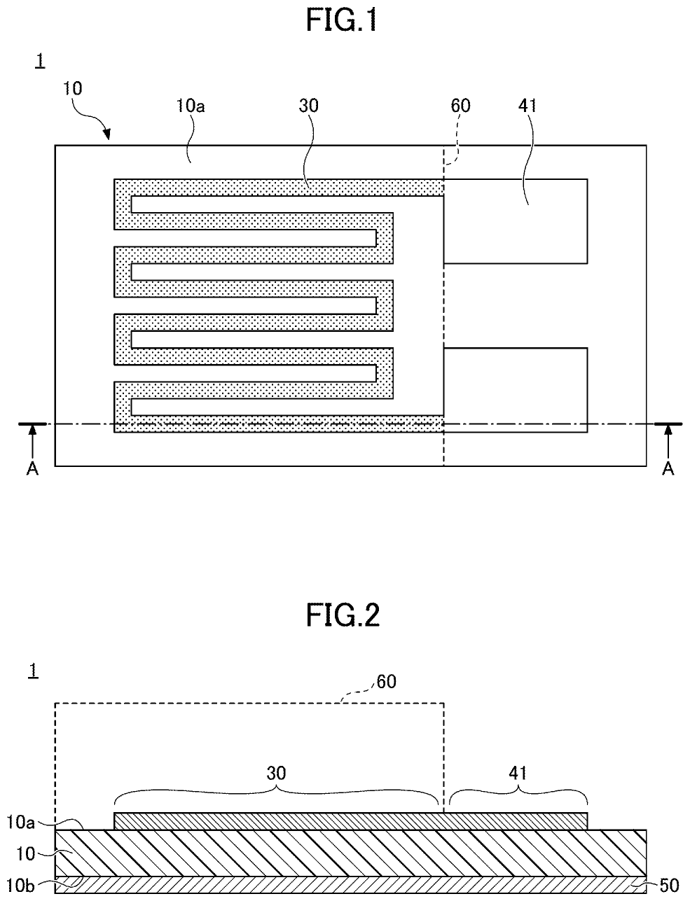

FIG. 1 is a plan view of an example of a strain gauge according to a first embodiment. FIG. 2 is a cross-sectional view of an example of the strain gauge according to the first embodiment, and illustrates the cross section taken along the A-A line in FIG. 1. Referring to FIGS. 1 and 2, a strain gauge 1 includes a substrate 10, a resistor 30, terminal sections 41, and a conductive layer 50.

In the present embodiment, for the sake of convenience, for the strain gauge 1, the side of the substrate 10 where the resistor 30 is provided is referred to as an upper side or one side, and the side of the substrate 10 where the resistor 30 is not provided is referred to as a lower side or another side. Further, for each component, the surface on the side where the resistor 30 is provided is referred to as one surface or an upper surface, and the surface on the side where the resistor 30 is not provided is referred to as another surface or a lower surface. However, the strain gauge 1 can be used in a state of being upside down, or can be disposed at any angle. Further, a plan view means that an object is viewed in a direction normal to an upper surface 10a of the substrate 10, and a planar shape refers to a shape of an object when viewed in the direction normal to the upper surface 10a of the substrate 10.

The substrate 10 is a member that is a base layer for forming the resistor 30 or the like, and is flexible. The thickness of the substrate 10 is not particularly restricted and can be appropriately selected for any purpose. For example, such a thickness can be approximately between 5 μm and 500 μm. In particular, when the thickness of the substrate 10 is between 5 μm and 200 μm, it is preferable in terms of strain transfer from a flexure element surface that is bonded to a lower surface of the substrate 10 via an adhesive layer or the like and of dimensional stability with respect to environment, and when the thickness is 10 μm or more, it is further preferable in terms of insulation.

The substrate 10 can be formed of an insulating resin film such as a PI (polyimide) resin, an epoxy resin, a PEEK (polyether ether ketone) resin, a PEN (polyethylene naphthalate) resin, a PET (polyethylene terephthalate) resin, a PPS (polyphenylene sulfide) resin, a LCP (liquid crystal polymer) resin, or a polyolefin resin. The film refers to a flexible member having a thickness of about 500 μm or less.

Here, the “formed of an insulating resin film” is not intended to preclude the substrate 10 from containing fillers, impurities, or the like in the insulating resin film. The substrate 10 may be formed of, for example, an insulating resin film containing fillers such as silica or alumina.

The resistor 30 is a thin film formed in a predetermined pattern and is a sensitive section where resistance varies in accordance with strain. The resistor 30 may be formed directly on the upper surface 10a of the substrate 10, or may be formed above the upper surface 10a of the substrate 10, via another layer. In FIG. 1, for the sake of convenience, the resistor 30 is illustrated in a crepe pattern.

The resistor 30 can be formed of, for example, material including Cr (chromium), material including Ni (nickel), or material including both Cr and Ni. In other words, the resistor 30 can be formed of material including at least one of Cr or Ni. An example of the material including Cr includes a Cr composite film. An example of the material including nickel includes Cu—Ni (copper nickel). An example of the material including both Cr and Ni includes Ni—Cr (nickel chromium).

Here, the Cr composite film is a composite film of Cr, CrN, and Cr₂N, and the like. The Cr composite film may include incidental impurities such as chromium oxide.

The thickness of the resistor 30 is not particularly restricted and can be appropriately selected for any purpose. The thickness can be, for example, approximately between 0.05 μm and 2 μm. In particular, when the thickness of the resistor 30 is 0.1 μm or more, it is preferable in terms of improvement in crystallinity (e.g., crystallinity of α-Cr) of a crystal that constitutes the resistor 30, and when the thickness of the resistor 30 is 1 μm or less, it is further preferable in terms of reductions in cracks of a given film caused by internal stress of the film that constitutes the resistor 30, or of reductions in warp in the substrate 10.

By forming the resistor 30 on a functional layer 20, the resistor 30 having a stable crystalline phase can be formed. With this arrangement, gauge characteristics (a gauge factor, a gauge factor temperature coefficient TCS, and temperature coefficient of resistance TCR) can be improved stably.

For example, when the resistor 30 is a Cr composite film, the functional layer 20 is provided, and thus the resistor 30 can be formed with α-Cr (alpha-chromium) as a main component. The α-Cr has a stable crystalline phase and thus stability of the gauge characteristics can be improved. Here, the main component means that a target substance is at 50% by weight or more of total substances that constitute the resistor. When the resistor 30 is the Cr composite film, the resistor 30 preferably includes α-Cr at 80% by weight or more, from the viewpoint of improving the gauge characteristics. More preferably, the resistor 30 includes α-Cr at 90% by weight or more. The α-Cr is Cr having a bcc structure (body-centered cubic structure).

When the resistor 30 is the Cr composite film, CrN and Cr₂N included in the Cr composite film are preferably at 20% by weight or less. When CrN and Cr₂N included in the Cr composite film are at 20% by weight or less, reductions in the gauge factor can be suppressed.

A percentage of Cr₂N in the CrN and Cr₂N is preferably greater than or equal to 80% and less than 90%, and more preferably greater than or equal to 90% and less than 95%. When the percentage of Cr₂N in the CrN and Cr₂N is greater than or equal to 90% and less than 95%, TCR (negative TCR) is further reduced significantly by Cr₂N having a semiconductor characteristic. Further, with reductions in making of ceramics, brittle fracture is reduced.

When a trace amount of N₂ or atomic N, which is mixed into a given film, is present, the external environment (e.g., in a high temperature environment) causes the trace amount of N₂ or atomic N to escape from the given film, thereby resulting in changes in film stress. By creating chemically stable CrN, a stable strain gauge can be obtained without forming the unstable N.

The terminal sections 41 respectively extend from both end portions of the resistor 30 and are each wider than the resistor 30 to be in an approximately rectangular shape, in a plan view. The terminal sections 41 are a pair of electrodes for externally outputting changes in a resistance value of the resistor 30 in accordance with strain, and for example, a lead wire or the like for an external connection is joined to each terminal section. For example, the resistor 30 extends from one terminal section 41, with zigzagged hairpin turns, to be connected to another terminal section 41. The upper surface of each terminal section 41 may be coated with a metal allowing for better solderability than the terminal section 41. For the sake of convenience, the resistor 30 and the terminal sections 41 are indicated by different numerals. However, the resistor and the terminal sections can be integrally formed of the same material, in the same process.

The conductive layer 50 is formed on the lower surface 10b of the substrate 10. The conductive layer 50 is a layer that is formed to reduce noise superimposed at the resistor, and is formed of a material having a higher electrical conductivity than the substrate 10. By forming the conductive layer 50 on the lower surface 10b of the substrate 10 to reduce noise superimposed at the resistor, reductions in measurement accuracy of the strain gauge 1 can be suppressed.

By forming the conductive layer 50 on the lower surface 10b of the substrate 10, when, for example, measurement is performed in the environment (for example, low humidity) in which noise such as static electricity is likely to occur, an effect or the like of reducing a TCR value or variations in an output voltage, which is supplied during applying of strain, is obtained. Particularly, an extremely sensitive strain gauge, of which the gauge factor is 10 or more and that uses a Cr composite film, is likely to be influenced by static electricity generated from a measurement target such as a motor, because the strain gauge has higher sensitivity. Accumulation of the static electricity on the substrate tends to cause measurement errors of the output voltage or variations in the output voltage. Therefore, for the extremely sensitive strain gauge of which the gauge factor is 10 or more and that uses the Cr composite film, a remarkable effect of forming the conductive layer 50 is particularly obtained.

The conductive layer 50 is preferably electrically coupled to a reference potential (GND). Alternatively, when the strain gauge 1 is attached to the flexure element, the conductive layer 50 may be at the same potential as the flexure element. In any case, noise is reduced advantageously.

The conductive layer 50 can be formed of, for example, a metal, an alloy, or a laminated film in which at least one of the metal or alloy is laminated. More specifically, an example of the material of the conductive layer 50 includes an alloy of any metals selected from among Cu, Ni, Al, Ag, Au, Pt, Pd, Sn, Cr, and the like, or, a laminated film in which any one or more metals or alloys are appropriately laminated. The same material (e.g., a Cr composite film) as the resistor 30 may be used as the material of the conductive layer 50.

Alternatively, the conductive layer 50 may be formed of an oxide film such as tin-doped indium oxide (ITO), fluorine-doped tin oxide (FTO), or antimony-doped tin oxide (ATO), or of a resin film or the like that contains conductive fillers.

The thickness of the conductive layer 50 can be, for example, greater than or equal to 0.1 μm and less than or equal to 5 μm. When the thickness of the conductive layer 50 is 0.1 μm or more, an effect of reducing noise is sufficiently obtained. When the thickness of the conductive layer 50 is 5 μm or less, a given film can be easily formed without forming cracks in the conductive layer 50.

Further, when the conductive layer 50 is formed on the lower surface 10b of the substrate 10, an effect of preventing the charging of the substrate 10, an effect of homogenizing heat distribution for the strain gauge 1, and an effect of preventing the absorption of water into the substrate 10 are obtained.

For example, there are cases where an insulating resin film that is used as the substrate 10 is unwound from a roll and then a predetermined process is performed. In this case, if the conductive layer 50 is not formed, the outside of the insulating resin film roll is peeled from the inside of the roll, during unwinding of the insulating resin film from the roll, and thus static electricity is generated. Therefore, the surface of the insulating resin film is charged. With the charging of the surface of the insulating resin film, contamination adheres to the surface of the insulating resin film, thereby resulting in a reduced yield. By forming the conductive layer 50 on the lower surface 10b of the substrate 10, the substrate 10 can be prevented from being charged and thus adhesion of the contamination to the surface of the substrate 10 can be suppressed. The upper surface 10a-side of the substrate 10 is prevented from being charged through the resistor 30.

When the sheet resistance of the conductive layer 50 is 10⁴ [ω/□] or less, charging is not performed. When the sheet resistance is between 10⁸ and 10⁴ [ω/□], charging is less likely to be performed. When the sheet resistance is between 10¹¹ and 10⁸ [Ω/□], charging is performed. However, the charge can be reduced. In consideration of the above situations, the sheet resistance of the conductive layer 50 is preferably selected based on an application environment or the like, in order to obtain an antistatic effect. The sheet resistance can be adjusted by changing a film thickness of the conductive layer 50.

A cover layer 60 (insulating resin layer) may be disposed on and above the upper surface 10a of the substrate 10, such that the resistor 30 is coated and the terminal sections 41 are exposed. With the cover layer 60 being provided, mechanical damage and the like can be prevented from occurring in the resistor 30. Additionally, with the cover layer 60 being provided, the resistor 30 can be protected against moisture and the like. The cover layer 60 may be provided to cover all portions except for the terminal sections 41.

The cover layer 60 can be formed of an insulating resin such as a PI resin, an epoxy resin, a PEEK resin, a PEN resin, a PET resin, or a PPS resin, a composite resin (e.g., a silicone resin or a polyolefin resin). The cover layer 60 may contain fillers or pigments. The thickness of the cover layer 60 is not particularly restricted and can be appropriately selected for any purpose. For example, the thickness may be approximately between 2 μm and 30 μm.

In order to manufacture the strain gauge 1, first, the substrate 10 is prepared and the conductive layer 50 is formed on the lower surface 10b of the substrate 10. The material and thickness for the conductive layer 50 are set as described above. The conductive layer 50 can be formed on the lower surface 10b of the substrate 10 by using a laminate of rolled foil, for example. The conductive layer 50 may be formed on the lower surface 10b of the substrate 10 by sputtering, plating, or the like. With this arrangement, by forming the conductive layer 50 on the lower surface 10b of the substrate 10 first, even when a roll is used in a subsequent process, charging of the substrate 10 can be prevented, and thus adhesion of contamination to the surface of the substrate 10 can be suppressed.

Next, the resistor 30 and the terminal sections 41, which have the planar shape as illustrated in FIG. 1, are formed on the upper surface 10a of the substrate 10. The material and thickness for each of the resistor 30 and terminal sections 41 are set as described above. The resistor 30 and terminal sections 41 can be integrally formed of the same material.

The resistor 30 and the terminal sections 41 can be deposited, for example, such that a source material capable of forming the resistor 30 and the terminal sections 41 is a target to be deposited by magnetron sputtering, and such that patterning is performed by photolithography. Instead of magnetron sputtering, the resistor 30 and the terminal sections 41 may be deposited by reactive sputtering, vapor deposition, arc ion plating, pulsed laser deposition, or the like.

From the viewpoint of stabilizing the gauge characteristics, before depositing of the resistor 30 and the terminal sections 41, the functional layer, as a base layer, that has a film thickness that is approximately between 1 nm and 100 nm, is preferably vacuum-deposited on the upper surface 10a of the substrate 10, by conventional sputtering, for example. After forming of the resistor 30 and the terminal sections 41 on the entire upper surface of the functional layer, the functional layer, as well as the resistor 30 and the terminal sections 41, are patterned in the planar shape illustrated in FIG. 1, by photolithography.

In the present application, the functional layer refers to a layer that has a function of promoting crystal growth of the resistor 30 that is at least an upper layer. Also, the functional layer preferably has a function of preventing oxidation of the resistor 30 caused by oxygen and moisture that are contained in the substrate 10, as well as a function of improving adhesion between the substrate 10 and the resistor 30. The functional layer may further have other functions.

The insulating resin film that constitutes the substrate 10 contains oxygen and moisture. In this regard, particularly when the resistor 30 includes Cr, it is effective for the functional layer to have a function of preventing oxidation of the resistor 30, because Cr forms an autoxidized film.

The material of the functional layer is not particularly restricted as long as it is material having a function of promoting crystal growth of the resistor 30 that is at least an upper layer. Such material can be appropriately selected for any purpose and includes one or more metals selected from the group consisting of, for example, Cr (chromium), Ti (titanium), V (vanadium), Nb (niobium), Ta (tantalum), Ni (nickel), Y (yttrium), Zr (zirconium), Hf (hafnium), Si (silicon), C (carbon), Zn (zinc), Cu (copper), Bi (bismuth), Fe (iron), Mo (molybdenum), W (tungsten), Ru (ruthenium), Rh (rhodium), Re (rhenium), Os (osmium), Ir (iridium), Pt (platinum), Pd (palladium), Ag (silver), Au (gold), Co (cobalt), Mn (manganese), and Al (aluminum); an alloy of any metals among the group; or a compound of any metal among the group.

Examples of the above alloy include FeCr, TiAl, FeNi, NiCr, CrCu, and the like. Examples of the above compound include TiN, TaN, Si₃N₄, TiO₂, Ta₂O₅, SiO₂, Cr₂O₃, CrN, Cr₂N, and the like.

In particular, Cr₂O₃, CrN, Cr₂N, Ti, TiO₂, Ta₂O₅, NiCr, Ni, SiO₂, Si₃N₄, among the metal, the metal compound, and the like, are preferably used. This is because, when these materials are used, the effect of uniformly promoting crystal growth of the resistor 30 is obtained.

When the functional layer is formed of a conductive material such as a metal or an alloy, the film thickness of the functional layer is preferably one-fifth or less the film thickness of the resistor. When such a range is set, crystal growth of α-Cr can be promoted, and further, a portion of the current flowing through the resistor flows through the functional layer. Thus, reductions in detection sensitivity of strain can be prevented.

More preferably, when the functional layer is formed of the conductive material such as a metal or an alloy, the film thickness of the functional layer is one-tenth or less the film thickness of the resistor. When such a range is set, crystal growth of α-Cr can be promoted, and further, a portion of the current flowing through the resistor flows through the functional layer. Thus, reductions in detection sensitivity of strain can be further prevented.

When the functional layer is formed of the conductive material such as a metal or an alloy, the film thickness of the functional layer is further preferably one-hundredth or less the film thickness of the resistor. When such a range is set, a portion of the current flowing through the resistor flows through the functional layer, and thus reductions in detection sensitivity of strain can be further prevented.

When the functional layer is formed of an insulating material such as an oxide or a nitride, the film thickness of the functional layer is preferably between 1 nm and 1 μm. When such a range is set, crystal growth of α-Cr can be promoted, and thus a given film can be easily formed without having cracks in the functional layer.

When the functional layer is formed of the insulating material such as an oxide or a nitride, the film thickness of the functional layer is preferably between 1 nm and 0.8 μm. When such a range is set, crystal growth of α-Cr can be promoted, and further, a given film can be further easily formed without having cracks in the functional layer.

When the functional layer is formed of the insulating material such as an oxide or a nitride, the film thickness of the functional layer is more preferably between 1 nm and 0.5 μm. When such a range is set, crystal growth of α-Cr can be promoted, and further, a given film can be formed more easily without having cracks in the functional layer.

The planar shape of the functional layer is patterned to be substantially the same as the planar shape of the resistor as illustrated in FIG. 1. However, the planar shape of the functional layer is not limited when it is substantially the same as the planar shape of the resistor. When the functional layer is formed of an insulating material, the planar shape of the functional layer may not be patterned to be the same shape as the planar shape of the resistor. In this case, the functional layer may be solidly formed to correspond to a region where at least the resistor is formed. Alternatively, the functional layer may be solidly formed on the entire top surface of the substrate 10.

When the functional layer is formed of an insulating material, the functional layer is formed to be relatively thick such that the thickness of the functional layer is greater than or equal to 0.05 μm and less than or equal to 1 μm, and further, the functional layer is formed solidly. With this arrangement, the thickness and surface area of the functional layer are increased, and thus heat obtained when the resistor generates the heat can be dissipated toward the substrate 10. As a result, in the strain gauge 1, reductions in measurement accuracy due to self-heating of the resistor can be suppressed.

The functional layer can be vacuum-deposited by, for example, conventional sputtering in which a source material capable of forming the functional layer is the target and in which an Ar (argon) gas is supplied to a chamber. By using conventional sputtering, the functional layer is deposited while the upper surface 10a of the substrate 10 is etched with Ar. Thus, a deposited amount of the film of the functional layer is minimized and thus the effect of improving adhesion can be obtained.

However, this is an example of a method of depositing the functional layer, and the functional layer may be formed by other methods. For example, before depositing of the functional layer, the upper surface 10a of the substrate 10 is activated by plasma treatment or the like using Ar or the like to thereby obtain the effect of improving the adhesion, and subsequently, the functional layer may be vacuum-deposited by magnetron sputtering.

A combination of the material of the functional layer and the material of the resistor 30 and the terminal sections 41 is not particularly restricted, and can be appropriately selected for any purpose. For example, Ti is used for the functional layer, and a Cr composite film formed with α-Cr (alpha-chromium) as the main component can be deposited as the resistor 30 and the terminal sections 41.

In this case, each of the resistor 30 and the terminal sections 41 can be deposited by, for example, magnetron sputtering in which a source material capable of forming the Cr composite film is the target and in which an Ar gas is supplied to a chamber. Alternatively, the resistor 30 and the terminal sections 41 may be deposited by reactive sputtering in which pure Cr is the target and in which an appropriate amount of nitrogen gas, as well as an Ar gas, are supplied to a chamber. In this case, by changing a supplied amount of the nitrogen gas or pressure (nitrogen partial pressure) of the nitrogen gas, or by providing a heating process to adjust heating temperature, a percentage of CrN and Cr₂N included in the Cr composite film, as well as a percentage of Cr₂N in CrN and Cr₂N, can be adjusted.

In such methods, a growth face of the Cr composite film is defined by the functional layer formed of Ti, and the Cr composite film that is formed with α-Cr as the main component having a stable crystalline structure can be deposited. Also, Ti that constitutes the functional layer is diffused into the Cr composite film, so that the gauge characteristics are improved. For example, the gauge factor of the strain gauge 1 can be 10 or more, as well as the gauge factor temperature coefficient TCS and temperature coefficient of resistance TCR being able to be each in the range of from −1000 ppm/° C. to +1000 ppm/° C. When the functional layer is formed of Ti, the Cr composite film may include Ti or TiN (titanium nitride).

When the resistor 30 is the Cr composite film, the functional layer formed of Ti includes all functions of a function of promoting crystal growth of the resistor 30, a function of preventing oxidation of the resistor 30 caused by oxygen or moisture contained in the substrate 10, and a function of improving adhesion between the substrate 10 and the resistor 30. Instead of Ti, when the functional layer is formed of Ta, Si, Al, or Fe, the functional layer also includes the same functions.

As described above, with the functional layer being provided in the lower layer of the resistor 30, the crystal growth of the resistor 30 can be promoted and thus the resistor 30 having a stable crystalline phase can be fabricated. As a result, for the strain gauge 1, stability of the gauge characteristics can be improved. Also, a given material that constitutes the functional layer is diffused into the resistor 30, and thus the gauge characteristics of the strain gauge 1 can be improved.

After forming of the resistor 30 and the terminal sections 41, the cover layer 60 with which the resistor 30 is coated and that exposes the terminal sections 41 is formed on and above the upper surface 10a of the substrate 10, as necessary, so that the strain gauge 1 is completed. For example, the cover layer 60 can be fabricated such that a thermosetting insulating resin film in a semi-cured state is laminated on the upper surface 10a of the substrate 10, and such that the resistor 30 is coated therewith and the terminal sections 41 are exposed; subsequently, heat is added and curing is performed. The cover layer 60 may be formed such that a thermosetting insulating resin that is liquid or paste-like is applied to the upper surface 10a of the substrate 10, and such that the resistor 30 is coated therewith and the terminal sections 41 are exposed; subsequently, heat is added and curing is performed.

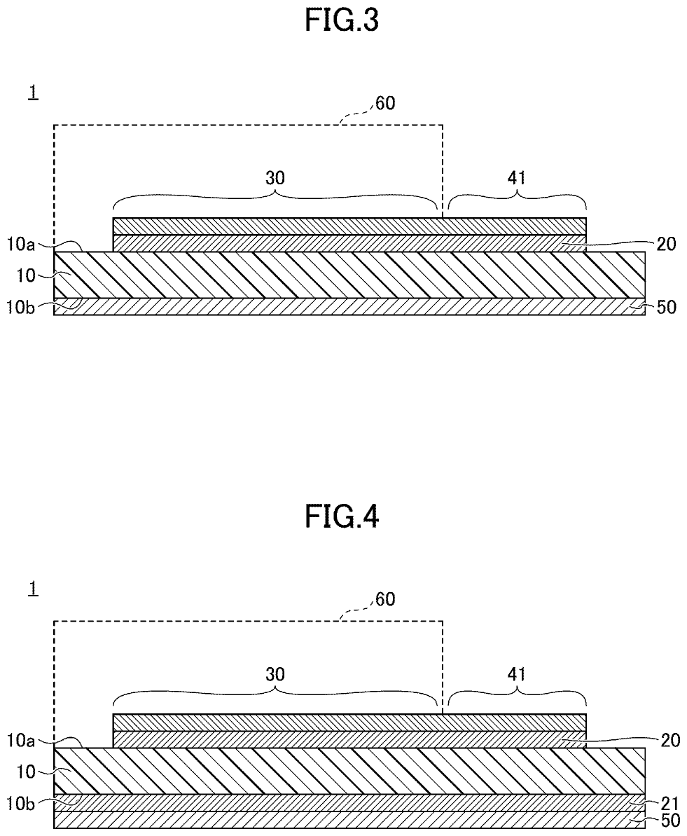

When the functional layer, as a base layer of the resistor 30 and the terminal sections 41, is provided on the upper surface 10a of the substrate 10, the strain gauge 1 has a cross-section shape illustrated in FIG. 3. A layer expressed by the numeral 20 indicates the functional layer. The planar shape of the strain gauge 1 in the case of providing the functional layer 20 is the same as that in FIG. 1.

As illustrated in FIG. 4, the functional layer 20 is be provided on the upper surface 10a of the substrate 10, and a functional layer 21 may be provided on the lower surface 10b of the substrate 10. In this case, the functional layer 20 and the functional layer 21 are each formed of the same material to have the same thickness, and the resistor 30, the terminals 41, and the conductive layer 50 may be each formed of the same material to have the same thickness. In such a structure, the upper and lower layer structures are substantially symmetrical with respect to the substrate 10, and thus warp of the strain gauge 1 can be reduced.

In this description, the same thickness means the same thickness in design, and covers a case where a given thickness differs according to an extent of manufacturing variations. In such a case, an effect of reducing warp of the strain gauge 1 is obtained.

### <First Modification of the First Embodiment>

The first modification of the first embodiment illustrates an example of the strain gauge having a layer structure different from that in the first embodiment. In the first modification of the first embodiment, description for the same component as that described in the above-mentioned embodiment may be omitted.

FIG. 5 is a cross-sectional view of the strain gauge according to the first modification of the first embodiment. Referring to FIG. 5, a strain gauge 1A differs from the strain gauge 1 (see FIGS. 1 and 2, and the like) in that the strain gauge 1A includes an insulating layer 70, which is formed of an inorganic material, on the lower surface 10b of the substrate 10 and that the conductive layer 50 is laminated on an opposite side of the insulating layer 70 from the substrate 10.

The insulating layer 70 is formed directly on the lower surface 10b of the substrate 10. An example of the material of the insulating layer 70 includes an oxide, a nitride, or a nitrous oxide of a metal, such as Cu, Cr, Ni, Al, Fe, W, Ti, or Ta, or an alloy of metals among the metals. An oxide, a nitride, or a nitrous oxide of a semiconductor such as Si or Ge may be used as the material of the insulating layer 70. The thickness of the insulating layer 70 may be, for example, approximately between 0.01 μm and 2 μm.

A method of forming the insulating layer 70 is not particularly restricted and can be selected for any purpose. For example, a vacuum process such as sputtering, plating, or chemical vapor deposition (CVD), or, a solution process such as spin coating or sol-gel process is used.

By forming the insulating layer 70, a current flows through the resistor 30 to generate heat, and the heat transferred to the substrate 10 is efficiently transferred to the conductive layer 50. The transferred heat can be dissipated via the conductive layer 50. As a result, in the strain gauge, reductions in measurement accuracy due to self-heating of the resistor 30 can be suppressed.

### <Second Modification of the First Embodiment>

A second modification of the first embodiment illustrates another example of the strain gauge that has a layer structure different from that in the first embodiment. In the second modification of the first embodiment, description for the same component as that in the above embodiments may be omitted.

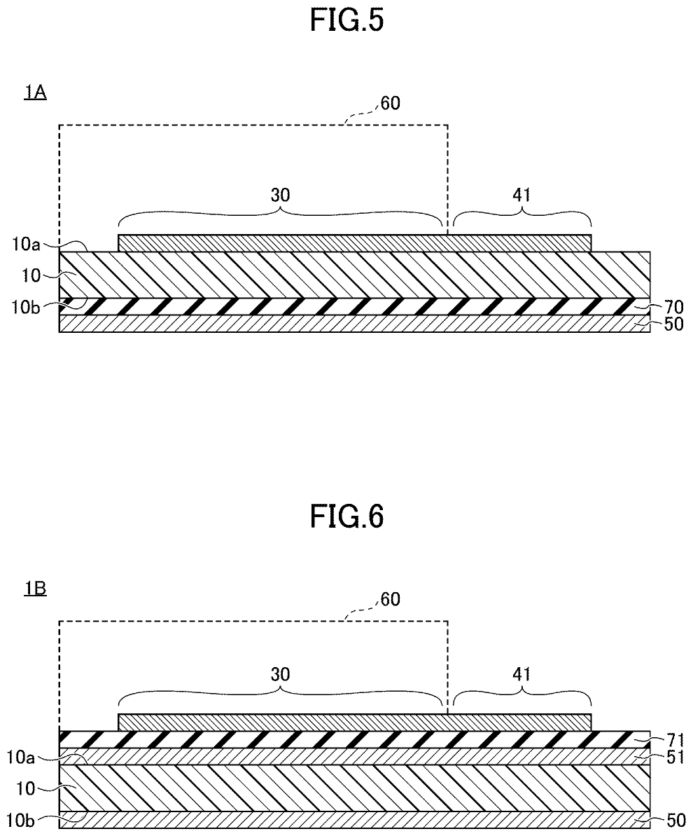

FIG. 6 is a cross-sectional view of the strain gauge according to the second modification of the first embodiment. Referring to FIG. 6, a strain gauge 1B differs from the strain gauge 1 (see FIGS. 1 and 2, and the like) in that conductive layers are formed on both sides of the substrate 10.

The strain gauge 1B includes the conductive layer 50, which is formed on the lower surface 10b of the substrate 10, and includes a conductive layer 51 formed on the upper surface 10a of the substrate 10.

The strain gauge 1B includes an insulating layer 71 laminated on an opposite side of the conductive layer 51 from the substrate 10. The resistor 30 and terminal sections 41 are laminated on an opposite side of the insulating layer 71 from the conductive layer 51.

The material and thickness of the conductive layer 51 can be appropriately selected from respective ranges of materials and thicknesses as illustrated for the conductive layer 50 in the first embodiment. However, the material and thickness of the conductive layer 51 may be the same as the material and thickness of the conductive layer 50, or may be different from the material and thickness of the conductive layer 50. The material and the thickness of the insulating layer 71 can be appropriately selected from respective ranges of materials and thicknesses as illustrated for the insulating layer 70 in the first modification of the first embodiment.

In such a manner, conductive layers may be respectively formed on both sides of the substrate 10. With this arrangement, an effect of reducing noise that occurs between the terminal sections 41, an effect of preventing charging of the substrate 10, an effect of homogenizing heat distribution for the strain gauge 1B, and an effect of preventing absorption of water into the substrate 10 can be increased in comparison to a case where a given conductive layer is provided on one surface of the substrate 10.

In the strain gauge 1B, the insulating layer 70 may be formed between the lower surface 10b of the substrate 10 and the upper surface of the conductive layer 50, as in the strain gauge 1A.

### <Third Modification of the First Embodiment>

A third modification of the first embodiment illustrates yet another example of the strain gauge in which a layer structure is different from that in the first embodiment. In the third modification of the first embodiment, description for the same component as that in the above embodiments may be omitted.

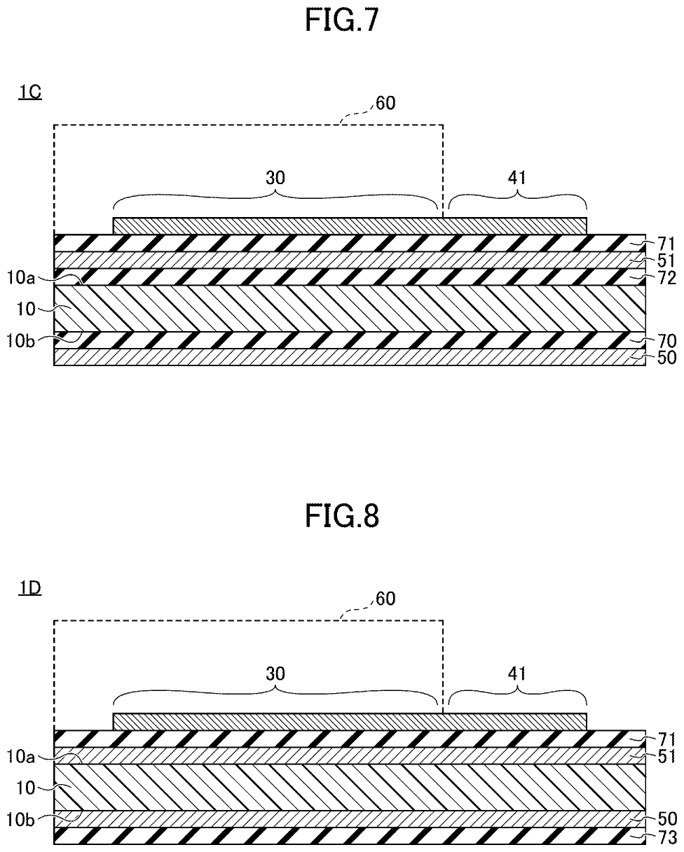

FIG. 7 is a cross-sectional view of the strain gauge according to the third modification of the first embodiment. Referring to FIG. 7, a strain gauge 1C differs from the strain gauge 1B (see FIG. 6) in that the strain gauge 1C includes an insulating layer 72 formed on the upper surface 10a of the substrate 10 and that the conductive layer 51 is laminated on an opposite side of the insulating layer 72 from the substrate 10. Also, the strain gauge 1C differs from the strain gauge 1B (see FIG. 6) in that the strain gauge 1C includes an insulating layer 70 on the lower surface 10b of the substrate 10 and that the conductive layer 50 is laminated on an opposite side of the insulating layer 70 from the substrate 10.

The material and the thickness of the insulating layer 72 can be appropriately selected from respective ranges of materials and thicknesses as illustrated for the insulating layer 70 in the first modification of the first embodiment. However, the same or different material and thickness for each of the insulating layers 70, 71, and 72 may be used.

As described above, insulating layers may be formed on both sides of the substrate 10. With this arrangement, an effect of increasing shape stability of the substrate is obtained.

### <Fourth Modification of the First Embodiment>

A fourth modification of the first embodiment further illustrates yet another example of the strain gauge in which a layer structure is different from that in the first embodiment. In the fourth modification of the first embodiment, description for the same component as that in the above embodiments may be omitted.

FIG. 8 is a cross-sectional view of the strain gauge according to the fourth modification of the first embodiment. Referring to FIG. 8, a strain gauge 1D differs from the strain gauge 1B (see FIG. 6) in that an insulating layer 73 is laminated on an opposite side of the conductive layer 50 from the substrate 10.

The material and the thickness of the insulating layer 73 can be appropriately selected from respective ranges of materials and thicknesses as illustrated for the insulating layer 70 in the first modification of the first embodiment. However, the same or different material and thickness for each of the insulating layers 71 and 73 may be used.

For example, the conductive layers 50 and 51 may be formed of the same metal, and the insulating layers 71 and 73 may be each formed of an oxide of the metal that constitutes a corresponding conductive layer among the conductive layers 50 and 51. Specifically, for example, the conductive layers 50 and 51 are formed of Al, and the insulating layers 71 and 73 may be each formed of an oxide of Al. In this case, the conductive layer 51 that is made of Al is formed on the upper surface 10a of the substrate 10, and the conductive layer 50 that is made of Al is formed on the lower surface 10b of the substrate 10.

Subsequently, thermal treatment is performed, and thus the insulating layer 71 that is made of Al₂O₃ is formed on the upper surface of the conductive layer 51, and further, the insulating layer 73 that is made of Al₂O₃ can be formed on the lower surface of the conductive layer 50. The conductive layers 50 and 51 have the same material, and thus the insulating layer 71 and insulating layer 73, which are formed in the thermal treatment, have the same thickness.

For example, when the conductive layers 50 and 51 are formed of Al to have the same thickness, a total thickness of the conductive layer 51 and insulating layer 71 is the same as a total thickness of the conductive layer 50 and insulating layer 73, and the upper and lower layer structures are substantially symmetrical with respect to the substrate 10. Thus, warp of the strain gauge 1D can be reduced.

The conductive layers 50 and 51 may be formed by a laminate of rolled foil, or may be formed by sputtering, plating, or the like. When Al is used, a thin film that is formed by sputtering, plating, or the like is preferably used, in comparison to a case where rolling is used. When Al is rolled, anisotropy is provided. Thus, for an extremely sensitive strain gauge that uses a Cr composite film, gauge characteristics become unstable. In contrast, Al that constitutes a thin film causes increased isotropy, and thus longitudinal and lateral stress is reduced.

Therefore, the difference in gauge characteristics between samples is reduced, thereby increasing a yield.

### Example 1

First, a full bridge circuit was fabricated using the strain gauge 1 illustrated in FIG. 1. A polyimide film having a thickness of about 25 μm was used as the substrate 10, a Cr composite film having a thickness of about 0.2 μm was used as the resistor 30, and an Al film having a thickness of about 0.5 μm was used as the conductive layer 50. A cover layer 60 was not formed.

As a comparative example, a strain gauge in which the conductive layer 50 was removed from the strain gauge 1 illustrated in FIG. 1 was fabricated (for the sake of convenience, it is referred to as a strain gauge 1X). In the strain gauge 1X, the material and thickness for each of the substrate 10 and the resistor 30 were set as in the strain gauge 1 described above.

Next, for each of the strain gauges 1 and 1X, a constant voltage source and a voltmeter were used as measurement devices, and noise was measured through terminal sections that are output terminals of the bridge circuit.

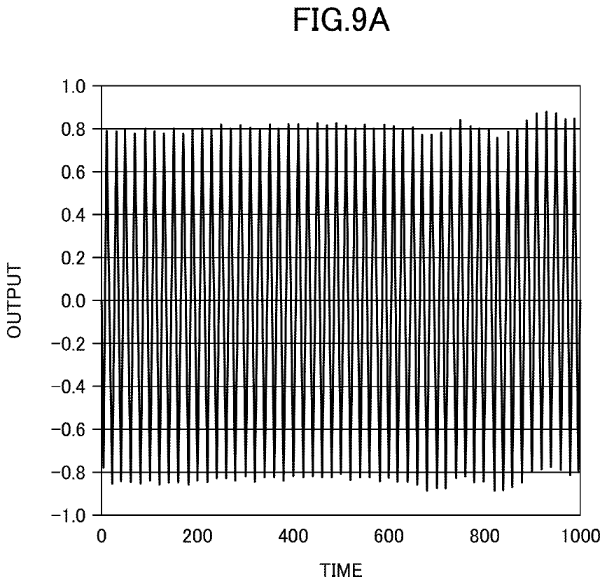

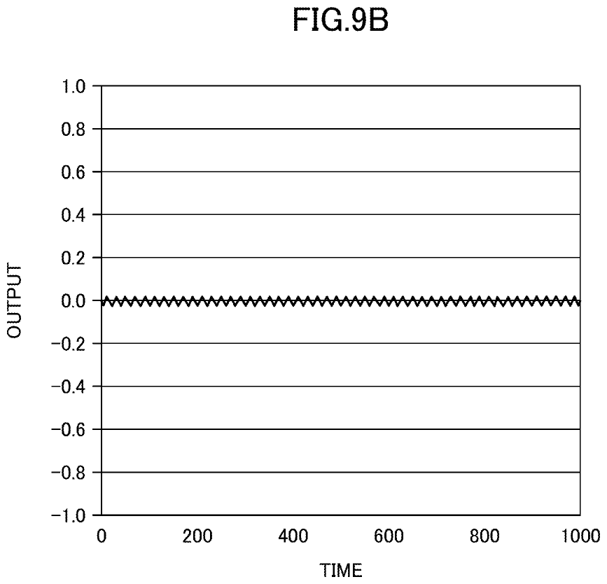

Results of noise measurement are illustrated in FIGS. 9A and 9B. FIG. 9A illustrates the measurement result for the strain gauge 1X. FIG. 9B illustrates the measurement result for the strain gauge 1. From FIGS. 9A and 9B, it has been confirmed that a peak noise level is significantly reduced for the strain gauge 1 in which the conductive layer 50 was formed, in comparison to the strain gauge 1X in which the conductive layer 50 was not formed.

Although the preferred embodiments and the like have been described above in detail, these embodiments and the like are not limiting. Various modifications and alternatives to the above embodiments and the like can be made without departing from a scope set forth in the claims.

For example, in each of the strain gauges 1A, 1B, and 1C, the functional layer 20 or/and 21 may be provided.

This International application claims priority to Japanese Patent Application Nos. 2020-052359, filed Mar. 24, 2020, and 2021-033200, filed Mar. 3, 2021, the contents of which are incorporated herein by reference in their entirety.

### REFERENCE SIGNS LIST

1, 1A, 1B, 1C, 1D strain gauge, 10 substrate, 10a upper surface, 10b lower surface, 20, 21 functional layer, 30 resistor, 41 terminal section, 50, 51 conductive layer, 60 cover layer, 70, 71, 72, 73 insulating layer

1. A strain gauge comprising:
a flexible resin substrate;
a resistor formed of material including at least one of chromium or nickel, the resistor being situated on one side of the substrate; and
a conductive layer formed on the other side of the substrate.

2. The strain gauge according to claim 1, further comprising an insulating layer formed of an inorganic material, the insulating layer being situated on the other side of the substrate,
wherein the conductive layer is laminated on an opposite side of the insulating layer from the substrate.

3. The strain gauge according to claim 1, further comprising:
a second conductive layer formed on the one side of the substrate; and
a second insulating layer formed of an inorganic material, the second insulating layer being laminated on an opposite side of the second conductive layer from the substrate,
wherein the resistor is laminated on an opposite side of the second insulating layer from the second conductive layer.

4. The strain gauge according to claim 3, further comprising: a third insulating layer formed of the inorganic material, the third insulating layer being situated on the one side of the substrate,
wherein the second conductive layer is laminated on an opposite side of the third insulating layer from the substrate.

5. The strain gauge according to claim 1, further comprising:
an insulating layer formed of an inorganic material, the insulating layer being laminated on an opposite side of the conductive layer from the substrate;
a second conductive layer formed on the one side of the substrate; and
a second insulating layer formed of the inorganic material, the second insulating layer being laminated on an opposite side of the second conductive layer from the substrate.

6. The strain gauge according to claim 5, wherein the conductive layer and the second conductive layer are formed of a same metal to have a same thickness, and
wherein the insulating layer and the second insulating layer are each formed of an oxide of the metal to have a same thickness.

7. The strain gauge according to claim 1, further comprising a functional layer formed of a metal, an alloy, or a metal compound, the functional layer being situated on a substrate side of the resistor, and the functional layer contacting the resistor.

8. The strain gauge according to claim 1, further comprising:
a functional layer formed of a metal, an alloy, or a metal compound, the functional layer being situated on a substrate side of the resistor, and the functional layer contacting the resistor and the substrate; and
a second functional layer formed of the metal, the alloy, or the metal compound, the second functional layer being situated on the substrate side of the conductive layer, and the second functional layer contacting the conductive layer and the substrate,
wherein the functional layer and the second functional layer are formed of a same material to have a same thickness, and
wherein the resistor and the conductive layer are formed of a same material to have a same thickness.

9. The strain gauge according to claim 1, wherein the resistor is formed of a film that includes Cr, CrN, and Cr₂N, a main component of the film being alpha-chromium.

10. The strain gauge according to claim 9, wherein CrN and Cr₂N included in the resistor are at 20% by weight or less.

11. The strain gauge according to claim 10, wherein a percentage of Cr₂N in the CrN and Cr₂N is greater than or equal to 80% and less than 90%.
